(19) United States
(12) Patent Application Publication
(10) Pub. No.: US 2005/0224977 A1
(43) Pub. Date: Oct. 13, 2005

(54) Wiring substrate and method using the same

(76) Inventors: Yusuke Yoshimura, Kaviya-shi (JP); Toshikazu Fujimoto, Ohmura-shi (JP); Toshiaki Arai, Yokohama-shi (JP)

Correspondence Address: RABIN & BERDO, P.C.;Suite 500, 1101 14th Street, N.W., Washington, DC, 20005, US

(21) Appl. No.: 11/044,716

(22) Filed: Jan. 28, 2005

(30) Foreign Application Priority Data
Jan. 29, 2004 (JP) 2004-020676
Jan. 29, 2004 (JP) 2004-020683

(51) Int. Cl. H01L 29/40; H01L 21/44

(52) U.S. Cl. 257/751; 257/762; 257/764; 438/687; 438/653; 438/656

(57) ABSTRACT

The present invention provides a wiring substrate. The wiring substrate includes a substrate, a copper wiring layer, and a diffusing barrier layer. The copper wiring layer is formed above the substrate and is made of copper or a material containing copper as a principal component. The diffusing barrier layer is formed on the copper wiring layer and is made of metal containing nitrogen. Meanwhile a method for manufacturing the wiring substrate is provided.

This application claims the benefit of Japan applications, Serial No. 2004-020676 and Serial No. 2004-020683, both filed Jan. 29, 2004, the subject matter of which is incorporated herein by reference.

### BACKGROUND OF THE INVENTION

1. Field of the Invention

The invention relates in general to a wiring substrate and method using the same, and more particularly to a wiring substrate applied in a display panel and method using the same.

2. Description of the Related Art

A liquid crystal display (LCD) panel is formed by sealing liquid crystals in between an alignment wiring substrate and a color filter substrate. Gate lines and signal lines are respectively configured in parallel on the wiring substrate of a present active matrix LCD panel, whereas the gate lines intersect with the signal lines. Furthermore, a thin film transistor (TFT) is configured with a set of intersecting gate line and signal line.

At present, the gate lines and signal lines on the wiring substrate are made of metal containing pure aluminum (Al) or molybdenum (Mo) and aluminum alloy for instant, as a principal component. The metal is etched by phosphoric/acetic/nitric (PAN)-series etching liquid to have a cross-section of a trapezoid shape.

In recently, with increasing high quality and frame scale requirement, wiring impedance and parasitic capacitance of the panel is enhanced to cause a serious wiring delay issue. As shown in FIG. 7, the square waves inputted to wires 30a, 30b of a wiring substrate 60, such as the square wave 31 shown at a left corner of the figure, are distorted as the wave 33 shown at a right corner of the figure in a transmission process due to the wiring delay issue. Therefore, the impedance of the wires 30a and 30b has to be lowered down so as to reduce the wiring delay issue. In practice, widening wires 30a and 30b can solve the issue but results in throughout drop. In order to maintain good throughout, one way is to thicken the wiring film. However, the chemical vapor deposition (CVD) insulation layer configured on the wiring film will loss the required insulation quality at the thinner part provided that its thickness is not increased accordingly. As a result, the step coverage is poor and thus manufacturing yield is reduced.

Materials having lower impedance, such as copper, may be used in wiring process to solve the above-mentioned problem, however, using copper as a wiring material has to conquer issues of copper diffusion, poor adhesion between copper and the substrate, and difficulty in forming a trapezoid pattern.

With regard to the first issue, a method for restraining copper diffusion is required to prevent copper diffusing in the amorphous silicon of TFT and causing a poor semiconductor performance. The second issue is mainly related to poor adhesion between the substrate and core metal copper for wiring and thus causes copper to peel off the substrate in the copper forming process. Besides, different from the conventional molybdenum and aluminum alloy, copper used for wiring core metal, has a higher etching rate than molybdenum. Therefore, the wiring pattern has a cross-section as shown in FIG. 6 in which the upper Mo layer is cut to have a roof (shelter) shape. When the later insulation layer is configuring with wires, the wiring configuration area will be reduced, thereby causing a product of poor quality. For this reason, a method for solving the third issue is required to form an isosceles trapezoid pattern.

According to a first patent of publication no. 353222 in 2003 (paragraphs 23 to 31), a method is illustrated for restraining copper diffusion by forming wolfram (W), rhenium (Re), or alloy of the former two metals and nickel (Ni) on the copper layer. However, it is difficult to form a smooth film of several hundred angstroms (Å) on copper by using this method, which causes an integration issue with the LCD manufacturing factory.

A stack structure formed by a tantalum (Ta) layer, a copper (Cu) layer, and a tantalum (Ta) layer in sequence can be considered. That is, the upper tantalum layer serves as a contact metal for restraining copper diffusion, the lower tantalum layer is used for tightly adhering the substrate glass. However, tantalum and copper etching in this method is a multi-stage process of dry etching, wet etching and dry etching, thereby providing a poor wiring pattern and increases production cost.

According to a second patent of publication no. 59191 in 2001 (paragraphs 0023 to 0031), a mixture solution of peroxy-sulfate, potassium hydride and hydrofluoric acid, or a mixture solution of peroxy-sulfate (KHSO₅, NaHSO₅, K₂S₂O₈, (NH₄)₂S₂O₈) and ammonium is illustrated as an etching solution. Furthermore, in wiring structure, the patent also shows a double-layer structure of copper/titanium or copper/ titanium alloy (with the titanium or titanium alloy formed under the copper layer).

However, according to the wiring structure in the second patent, there exists a disadvantage of copper diffusion, which reduces the required substrate insulation due to deposition of titanium or titanium alloy under the copper layer.

Provided that the wiring 30 of three layers molybdenum (Mo) 38, copper (Cu) 36 and molybdenum (Mo) 38 as shown in FIG. 8 is required, a PAN-series etching solution can be considered in etching process. However, different from nitric acid, the PAN-series etching solution etches the upper layer Mo 38 slower, and causes a side over etching of copper 36 in the end of etching. Therefore, in the case that the three layers Mo 34, Cu 36 and Mo 38 are sequentially deposited on the substrate 32, the upper layer Mo 38 will has a defect of incomplete etching.

Even the structure of two layers Cu 46 and Mo 44 as shown in FIG. 9 can form a correct trapezoid structure of a copper wiring layer 46, there is still no way for preventing copper diffusion at present.

### SUMMARY OF THE INVENTION

It is therefore an object of the invention to provide a wiring substrate to improve resistivity of the wiring core metal. Besides, the film impedance in the wiring structure can also be reduced to about a half. Reducing the wiring delay issue due to low impedance can develop a large and high-density substrate and improve its throughout.

The invention achieves the above-identified object by providing a wiring substrate including a substrate, a copper wiring layer and a diffusing barrier layer. The copper wiring layer is formed above the substrate and is made of copper or a material containing copper as a principal component. The diffusing barrier layer is formed on the upper surface or the upper surface and the sides of the copper wiring layer and is made of metal containing nitrogen. An adhesion layer is formed under the copper wiring layer and includes metal or metal containing nitrogen. The adhesion layer includes Mo, MoN, Ti, and TiN. The adhesion layer is directly formed upon the substrate. A deposition layer is formed on the substrate and the adhesion layer is directly formed upon the deposition layer. The deposition layer includes an insulation layer, a semiconductor layer, and a metal layer. The diffusing barrier layer includes molybdenum nitride (MoN) and titanium nitride (TiN). The copper wiring layer is directly formed upon the substrate. A deposition layer is formed on the substrate and the copper wiring layer is directly formed upon the deposition layer. The deposition layer includes an insulation layer, a semiconductor layer, and a metal layer.

The invention achieves the above-identified object by providing a method for forming a wiring substrate. The method includes the steps of preparing a substrate; depositing a copper wiring layer on the substrate, wherein the copper wiring layer is made of copper or a material containing copper as a principal component; patterning the copper wiring layer to form a copper wiring layer pattern; depositing a diffusing barrier layer on the copper wiring layer pattern, wherein the diffusing barrier layer is made of metal containing nitrogen; and patterning the diffusing barrier layer to distribute on an upper surface and sides of the copper wiring layer pattern.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1(a) is a cross-sectional view of a first type of wiring substrate in the invention.

FIG. 1(b) is a cross-sectional view of a second type of wiring substrate in the invention.

FIG. 1(c) is a cross-sectional view of a third type of wiring substrate in the invention.

FIG. 2(a) is a picture of a wiring structure cross-section taken by a TEM in which a diffusing barrier layer is formed without adding nitrogen gas in the reaction sputtering.

FIG. 2(b) is a picture of a wiring structure cross-section taken by a TEM in which a diffusing barrier layer is formed with a ratio of argon gas and nitrogen gas being 95:5 in the reaction sputtering.

FIG. 2(c) is a picture of a wiring structure cross-section taken by a TEM in which a diffusing barrier layer is formed with a ratio of argon gas and nitrogen gas being 70:30 in the reaction sputtering.

FIG. 3 is a line chart of resistivity and surface roughness (Rms) of the diffusing barrier layer relative to a ratio of argon gas amount over the total amount of argon gas and nitrogen gas.

FIG. 4 is a line chart of a fail time of each tested substance Cu, TiN(30%), Mo relative to an electrical filed strength in the insulation destroying test.

FIG. 5(a) is a cross-sectional view of a wiring substrate in the step (8) of forming a diffusing barrier layer on the copper wiring layer in the invention.

FIG. 5(b) is a cross-sectional view of a wiring substrate in the step (10) of exposing the wiring substrate from the bottom side of the substrate in the invention.

FIG. 5(c) is a cross-sectional view of a wiring substrate in the step (11) of wet etching process in the invention.

FIG. 6(Prior Art) is a cross-sectional view of a poor wiring structure.

FIG. 7(Prior Art) is a schematic diagram of a conventional wiring delay.

FIG. 8(Prior Art) is a schematic diagram of a poor step structure of Mo, Cu, and Mo layers.

FIG. 9(Prior Art) is a schematic diagram of a structure of Cu and Mo layers having completing an etching process.

FIG. 10 illustrates a relation between the (NH₄)₂S₂O₈ concentration and etching time of Cu wiring.

FIG. 11 illustrates Cu and Ti etching rate under a fixed (NH₄)₂S₂O₈ concentration of 5.0 g and 7.5 g/H₂O 500 ml.

FIGS. 12(a) and 12(b) illustrate a relation between etching time and etching amount as etching a deposition structure of Ti, Cu and Ti layers and a deposition structure of TiN, Cu and TiN layers by using a mixture solution of (NH₄)₂S₂O₈ and HF.

### DETAILED DESCRIPTION OF THE INVENTION

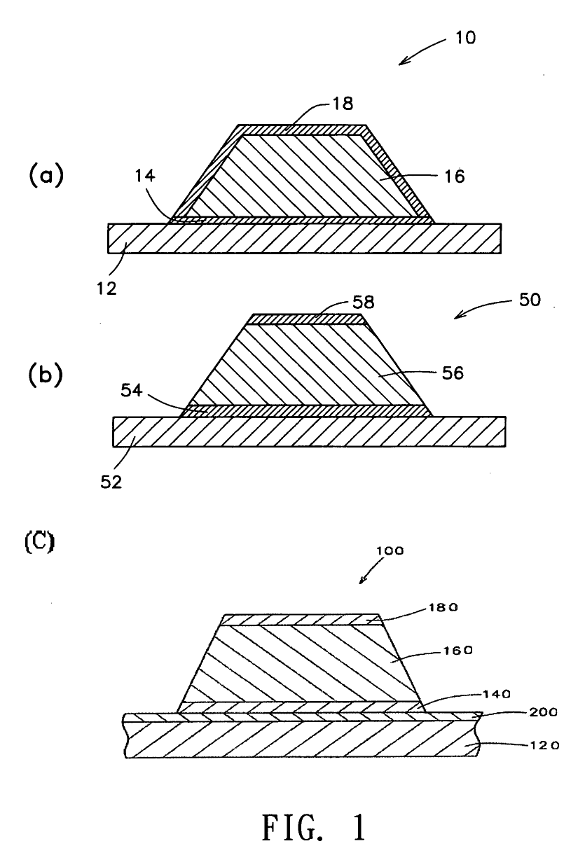

FIG. 1 illustrates a practice pattern of the wiring substrate in the invention. The invention can restrain copper diffusion of the wiring substrate, and can be applied in fields of panels having a copper wiring layer, particularly a liquid crystal display panel or an organic EL panel.

As shown in FIG. 1(a), the wiring substrate 10, which can restrain copper diffusion according to the invention, includes a substrate 12, an adhesion layer 14 composed of metal or a metal nitride, a copper wiring layer 16 formed on the adhesion layer 14, and a diffusing barrier layer 18 composed of a metal nitride covering the upper surface and two sides of the copper wiring layer 16.

In addition, FIG. 1(b) is another practice pattern of the wiring substrate. As shown in FIG. 1(b), the wiring substrate 50, which can restrain copper diffusion according to the invention, includes a substrate 52, an adhesion layer 54 composed of a metal and a metal nitride, a copper wiring layer 56 formed on the adhesion layer 54, and a diffusing barrier layer 58 covering the upper surface of the copper wiring layer 56.

The substrate 12 or 52 mentioned above can be a transparent glass or quartz. A glass substrate is exemplified for the substrate 12 or 52 in the following embodiment. However, the invention is not limited thereto, and can be applied to other substrates.

The adhesion layer 14 or 54 composed of metal or a metal nitride, such as Mo, MoN, Ti, TiN, the wiring layer 56 or 16, and the diffusing barrier layer 18 or 58 can be formed by a sputtering method. The adhesion layer 14 or 54 is provided to improve adhesion of the copper wiring layer 16 or 56 onto the substrate 12 or 52, and prevent ions in the substrate diffusing to the copper wiring layer 16 or 56 in manufacturing process and thus reducing the insulation of the copper wiring layer 16 or 56. The diffusing barrier layer 18 or 58 is provided to prevent copper in the copper wiring layer 16 or 56 from diffusing into and polluting an insulation film or a semiconductor layer formed thereto by a CVD process due to low melting point of the wiring layer 16 or 56.

The copper diffusion of the copper wiring layer 16 or 56 results from diffusion at the interface between the copper wiring layer and the contact layer thereof. Therefore, the wiring substrate 10 or 50 of the invention uses a diffusing barrier layer 16 or 56 having a dense amorphous structure to restrain the diffusion at the interface between the copper layer and the contact layer thereof. The metal nitrides used in the invention are preferred to be TiN and MoN. By controlling the nitrogen amount of these materials, the diffusing barrier layer 18 or 58 having a dense amorphous structure can be formed and will not have ions diffusing to other wiring layer or electrode layer.

The invention further provides an embodiment. The wiring substrate 100 as shown in FIG. 1(c) having the same feature as that described in FIG. 1(a) and FIG. 1(b), also includes an adhesion layer 140, a copper wiring layer 160 and a diffusing barrier layer 180 sequentially formed on the substrate 120. Therefore, any detail of its function and structure is not necessarily described here. Particularly, a deposition layer 200 is formed between the substrate 120 and the adhesion layer 140. The deposition layer 200 can be single layer or a multi-layer structure, and can be an insulation layer, a semiconductor layer, or a conduction layer. In the wiring substrate structure mentioned in FIGS. 1(a), 1(b) and 1(c), if the copper wiring layer has a good adhesion with the substrate or the deposition layer, the adhesion layer can be omitted.

The following table 1 illustrates steps of forming the wiring substrate 10 as shown in FIG. 1(a), which are divided into front process steps 1 to 7 and rear process steps 8 to 11.

TABLE 1

| | Step | Content |
|---|---|---|
| 1 | Cleaning | |
| 2 | Sputtering | MoN 150 Å |
| | | Cu 3000 Å |
| 3 | Photoresist coating | |
| 4 | Exposing | |
| 5 | Developing | |
| 6 | Wet etching | PAN-series |
| 7 | Photoresist stripping | |
| 8 | Sputtering | MoN 500 Å |
| 9 | Photoresist coating | |
| 10 | Rear-surface exposing | |
| | and | |
| 11 | Wet etching | PAN-series |
| 12 | Photoresist stripping | |

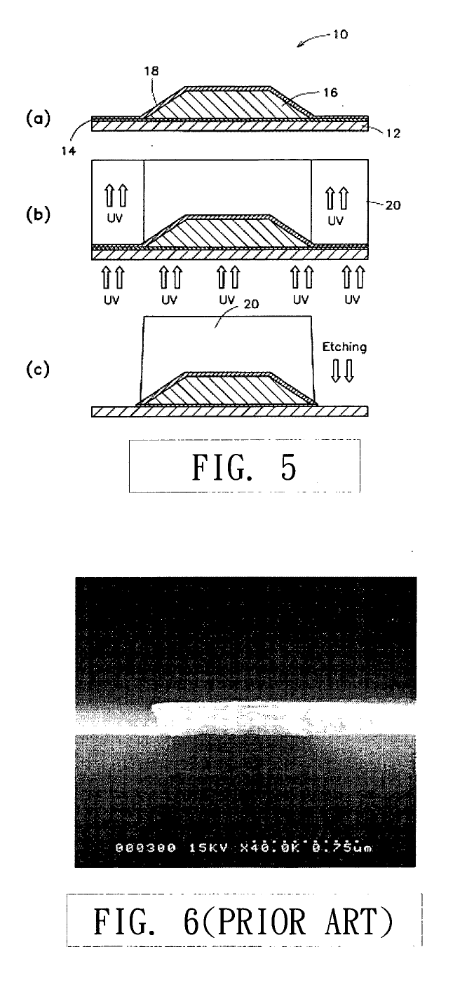

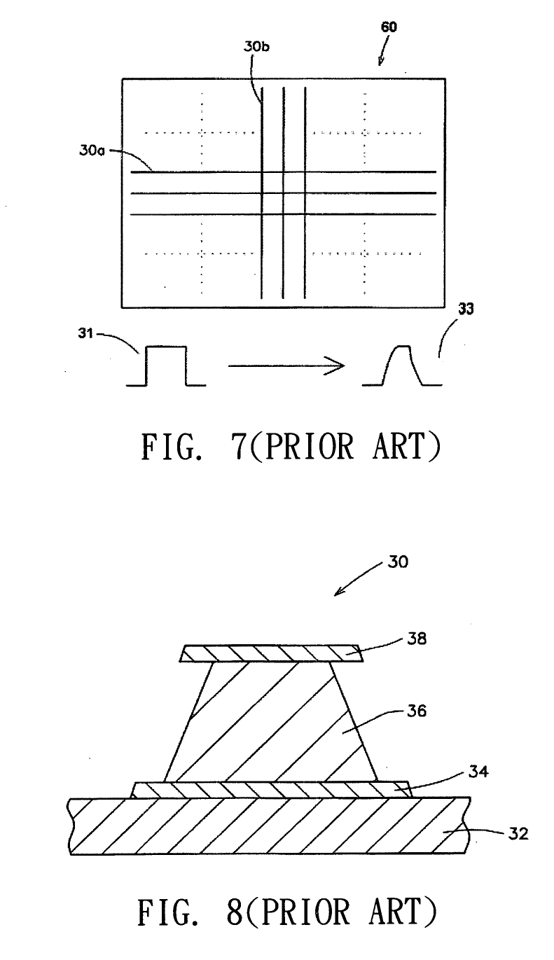

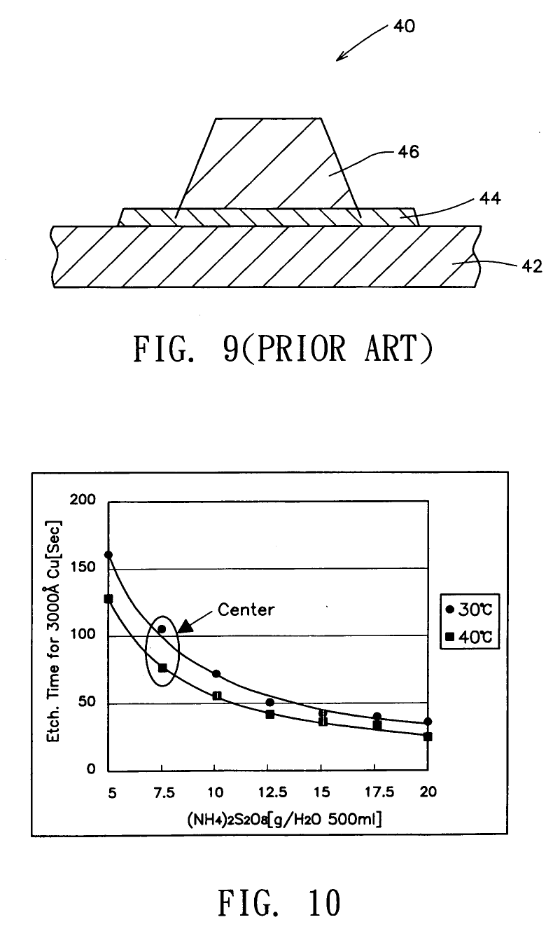

The front process steps 1 to 7 of the wiring substrate 10 in the invention includes a step (1) of preparing and cleaning a glass substrate 12, a step (2) of covering an adhesion layer 14 composed of metal or a metal nitride such as MoN, TiN on the substrate 10 and covering a copper (Cu) layer on the adhesion layer 14, a step (3) of performing photoresist coating on the copper layer, a step (4) of exposing one side of the photoresist on the copper layer, a step (5) of developing the photoresist to form a copper wiring pattern, a step (6) of wet etching the copper layer by PAN-series etching solution (Phosphoric acid, Acetic acid, Nitric acid) to form a pattern of copper wiring layer 16, and a step (7) of photoresist stripping. The front process steps are for covering an adhesion layer 14 on the substrate 12 and defining a pattern of copper wiring layer 16 (not shown in the figure but can be imagined as the substrate 10 in FIG. 5(a) before sputtering the diffusing barrier layer 18.

Besides, the front process of the wiring substrate 10 mentioned above does not require an extra device, substantially the same as the conventional manufacturing process of a wiring substrate using aluminum (Al). Two different points in the front process are that the sputtering material is changed from Al or Al—Nd alloy to Cu and that the PAN-series etching solution has a different composition.

Moreover, the rear process steps 8 to 11 of the wiring substrate in the invention includes a step (8) of forming a diffusing barrier layer 18 composed of a metal nitride such as MoN, TiN on the copper wiring layer 16 by sputtering, a step (9) of performing photoresist coating on the diffusing barrier layer 18, a step (10) of exposing the wiring substrate from the bottom side of the glass substrate by using the copper layer as a photomask and then developing the photoresist, a step (11) of wet etching the adhesion layer 14 and the diffusing barrier layer 18 by using a PAN-series etching solution, and a step (12) of stripping the photoresist.

FIGS. 5(a), 5(b) and 5(c) are cross-sectional views of the wiring substrate 10 in the invention respectively corresponding to steps (8), (9), (10) and (11). FIG. 5(a) illustrates that an adhesion layer 14 completely covers the substrate 12 and a diffusing barrier layer 18 is formed by sputtering on the defined pattern of a copper wiring layer 16 as shown in step (8). FIG. 5(b) illustrates that a photoresist 20 is coated on the diffusing barrier layer as shown in step (9). Afterward, the steps (10) and (11) are performed to expose the wiring substrate from the bottom side of the glass substrate 12. Due to the exposing from the bottom side, exposing beams such as UV can pass non-copper wiring layer pattern region but not the region of copper wiring layer pattern 16. As a result, when the photoresist 20 is developed, the diffusing barrier layer 18 in region of copper wiring layer pattern 16 is not exposed and thus remained. Therefore, when a wet etching is performed by a PAN-series etching solution, as shown in FIG. 5(c), in the wet etching process of developing the photoresist 20 and using PAN-series etching solution to wet-etching the adhesion layer 14 and diffusing barrier layer 18, only the diffusing barrier layer 18 on the copper wiring layer 16 is remained.

According to the wiring substrate 10 of the invention mentioned above, the adhesion layer 14 can be etched along with the copper wiring layer 16 in etching process of patterning the copper wiring layer 16, or be etched along with the diffusing barrier layer 18 in etching process of patterning the diffusing barrier layer 18, or be etched after the step of patterning the diffusing barrier layer 18.

The manufacturing method and process can also be simplified to form the structure shown in FIGS. 1(b) and 1(c). As in step (2), simultaneously form a stack of a diffusing barrier layer 58, a copper or copper alloy layer 56, and an adhesion layer 54. Afterward, according to steps (3) to (5), simultaneously etch the three layers to form a correct trapezoid structure in step (6), and obtain the required wiring substrate in the step (7).

The etching solution used in the above-mentioned etching step can also be other solutions, such as a mixture solution of (NH₄)₂S₂O₈ and HF, in addition to the series of phosphoric, acetic, and nitric acid.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures. The features and performance of the wiring substrate in the invention will be further illustrated according to experiments described in the following embodiments.

Embodiment One

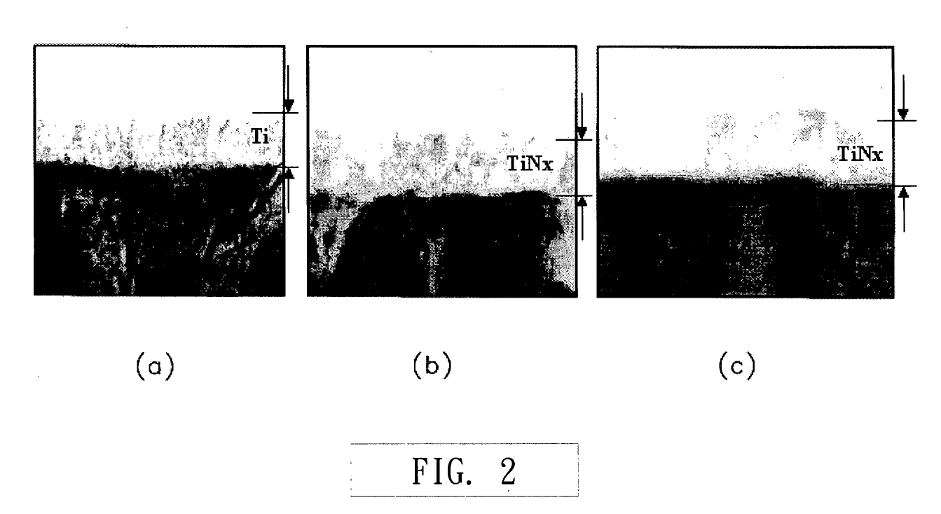

The amount of nitrogen gas.(N₂) is changed in the process of reaction sputtering using Ti and TiN, and then a transparent electronic microscope (TEM) is used to perform a structure analysis. In the Ti film formed without adding nitrogen as shown in FIG. 2(a), a pillar-like crystal structure is found. In the following reaction sputtering, as using the argon gas (Ar) added by nitrogen gas (N₂), the crystal structure is changed. When the ratio of Ar and N₂ is 95:5, as shown in FIG. 2(b), the above-mentioned pillar-like crystal structure is not so clear. If the added nitrogen gas has a higher ratio, for example, a ratio 70:30 of Ar and N₂, the pillar-like crystal structure of FIG. 2(a) disappears, and a dense amorphous structure can be found as shown in FIG. 2(c).

Embodiment Two

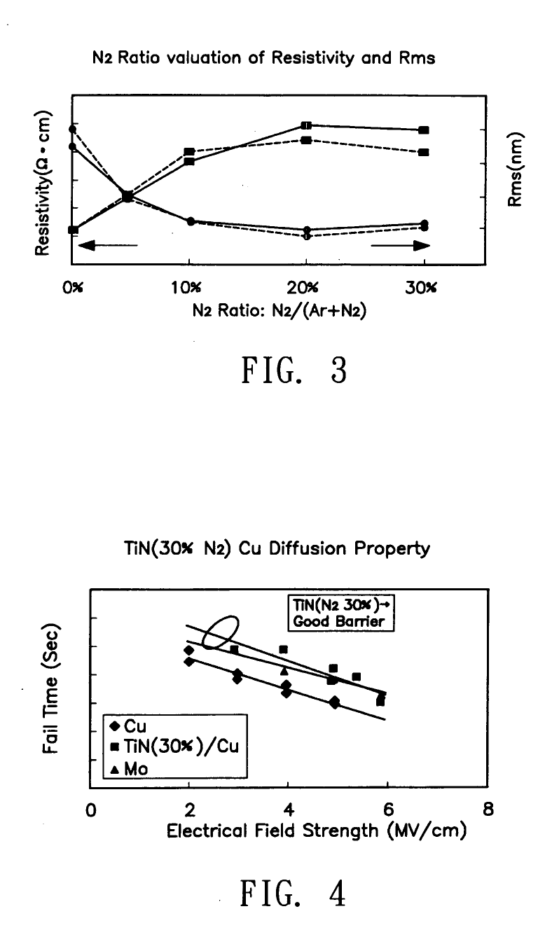

The same as the first embodiment, in the second embodiment, the N₂ amount added in the reaction sputtering is changed to measure resistivity and surface roughness (Rms) of Ti and TiN films as shown in FIG. 3. With regard to a diffusing barrier layer and an adhesion layer, the resistivity and surface roughness can be adjusted by controlling a nitrogen ratio. In FIG. 3, it can be shown that the higher is the nitrogen ratio, the higher is the resistivity and the lower is the surface roughness. Moreover, when the nitrogen ratio is about 30%, the resistivity and surface roughness is kept a constant value. Therefore, as shown in FIG. 3, if the nitrogen gas amount takes a percentage of 5% to 30% in the total amount of Ar and N₂, the film having the required impedance and flatness can be obtained.

Embodiment Three

In the third embodiment, in order to evaluate diffusing barrier features, a reliance experiment is performed by destroying substrate insulation under high temperature and high pressure conditions. Under the temperature 150° C., an insulation film of SiN having a thickness 1500 Å is placed along with a tested substance in an electric field. The diffusing barrier ability is monitored according to the recorded time that the insulation of the SiN film is reduced due to the tested substance diffusion (called as fail time). The tested substance is manufactured to be cylinder-shaped and have an area 1.346 mm². A molybdenum (Mo) material is used for comparison with the tested substance. The experiment group is Cu and TiN (30%) (the N₂ amount is 30% of the Ar amount). In FIG. 4, the TiN (30%) has better performance than Cu, or even the comparison group Mo, or the TiN (30%) has almost the same performance as the comparison group Mo. Therefore, the TiN is proved to have a diffusing barrier effect. On the other hand, although without drawings for illustration, TiN has a N₂ amount below 5% (the N₂ amount is only 5% of the Ar amount), it has no diffusing barrier effect.

Embodiment Four

As shown in Table 2, a conventional deposition structure of Mo and AINd layers is compared with a deposition structure of TiN, Cu and Ti layers in the invention. The diffusing barrier layer and core metal in the two structures have thickness of 500 Å and 3000 Å respectively. The adhesion layer of the TiN, Cu and Ti deposition structure, that is, the Ti film, has a thickness of 150.

TABLE 2

| | Mo/AINd | TiN/Cu/Ti |
|---|---|---|
| Top | Mo | TiN |
| Resistivity [E-6 Ω · cm] | 20 | 200 |
| Thickness [Å] | 500 | 500 |
| Core | AINd2% | Cu |
| Resistivity [E-6 Ω · cm] | 4.8 | 2.2 |
| Thickness [Å] | 3000 | 3000 |
| Bottom | — | Ti |
| Resistivity [E-6 Ω · cm] | 0 | 200 |
| Thickness [Å] | 0 | 150 |
| Sheet Resistivity [mΩ/□] | 153.8 | 73.2 |

According to Table 2, when the core metal is AINd, the resistivity is 4.8 μΩcm. When the core metal is Cu, the resistivity is 2.2 μΩcm. Therefore, the Cu material can be used to reduce resistivity of the wiring core metal. Moreover, even the wiring is considered into the substrate structure, the sheet resistivity can be also reduced to a half. The wiring of Mo and AlNd has a sheet resistivity of 154 mΩ/□. In comparison, the wiring substrate using TiN, Cu and Ti layers has only 73 mΩ/□, which is lower than that using Mo and AlNd.

Although the wiring substrate capable of restraining copper diffusion is illustrated according to the above-mentioned embodiments, the wiring substrate of the invention is not limited thereto. The core metal is composed of Cu or a layer composed of Cu as a principal component while the diffusing barrier layer and the adhesion layer can be formed by either one of MoN and TiN.

Embodiment Five

As shown in FIG. 1(c), the wiring substrate 100 is formed on the insulation substrate 120. The wiring substrate 100 includes an adhesion layer 140 composed of nitrogen on the insulation substrate 120, and a copper layer 160 formed on the adhesion layer 140. Afterward, a diffusing barrier layer 180 composed of nitrogen is formed on the copper layer 160. The adhesion layer 140 is formed on a deposition layer 200 located on the insulation substrate 120. For example, the deposition layer 200 can be a single transparent insulation layer including SiNx, TiOx, and organic polymer. The transparent insulation layer can prevent etching solution from etching the surface of insulation substrate 120. In other words, the transparent insulation layer plays a role of etching barrier. When the wiring substrate 100 is a TFT substrate, the wiring structure can be applied to a gate wiring structure and source/drain wiring structure. In the gate wiring structure, the deposition layer 200 is formed on the insulation substrate 120, and an adhesion layer 140, a copper layer 160, and a diffusing barrier layer 180 are sequentially formed on the deposition layer 200. The deposition layer 200 or the adhesion layer 140 can be omitted either or both. In the source/drain wiring structure, the source/drain wiring is formed on the deposition layer 200, and the deposition layer 200 can be a multi-layer structure composed of a gate metal layer, a gate insulation layer and a semiconductor layer. The adhesion layer 140, the copper layer 160, and the diffusing barrier layer 180 are sequentially formed on the deposition layer 200. The deposition layer 200 or the adhesion layer 140 can be omitted either or both.

The method for forming the wiring 100 in the invention is to sequentially deposit films and then form the required pattern by exposing, developing, and etching. In the invention, the solution for etching and patterning process is a mixture solution of (NH₄)₂S₂O₈ and HF, and has a PH value about 2 to 3. The (NH₄)₂S₂O₈ concentration is over 10(g/H₂O 1000 ml) and is preferred to be 7.5 (g/H₂O 500 ml). The HF concentration is over 2% while the HCI concentration is 0%.

In terms of TFT wiring substrate production, in comparison with etching of the copper wiring layer 160, the adhesion layer 140 and the diffusing barrier layer 180 can be etched within 120 sec, about between 30 sec and 120 sec. To reach the goal of completing etching within 30 sec to 120 sec, the (NH₄)₂S₂O₈ concentration should be over 5.0 (g/H₂O 500 ml). FIG. 10 illustrates a relation between the (NH₄)₂S₂O₈ concentration and etching time of Cu wiring. In FIG. 10, as the Cu wiring is etched at an etching rate of 30 Å/sec to 40 Å/sec, the (NH₄)₂S₂O₈ concentration is above 10 (g/H₂O 1000 ml) and is preferred to be 7.5 (g/H₂O 500 ml).

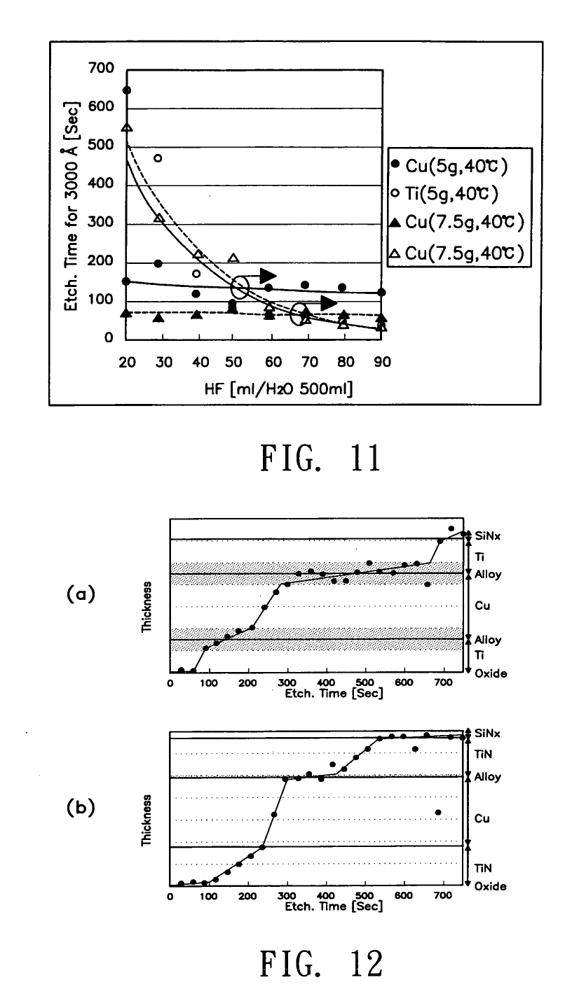

FIG. 11 illustrates Cu and Ti etching rate under a fixed (NH₄)₂S₂O₈ concentration of 5.0 g and 7.5 g/H₂O 500 ml. In FIG. 11, the Cu etching rate is fixed and not changed according to HF concentration. On the other hand, the Ti etching rate is direct proportional to the HF concentration, that is, the higher is the HF concentration, the faster is Ti etched. Ti etching ratio is 50 ml/H₂O 500 ml more than the Cu etching ratio. By doing so, the structure of TiN, Cu and TiN layers can have a cross-section of a better step shape, such as a trapezoid.

FIGS. 12(a) and 12(b) illustrates a relation between etching time and etching amount as etching a deposition structure of Ti, Cu and Ti layers and a deposition structure of TiN, Cu, and TiN layers by using a mixture solution of (NH₄)₂S₂O₈ and HF. The longitudinal axis represents a comparative thickness of each layer in the wring structure wherein dotted parts represent a diffusion layer generated at the interface between the copper layer and the upper layer or the lower layer. By comparing FIGS. 12(a) and 12(b), it can be found that the diffusion layer in the wiring structure of TiN, Cu and TiN layers in FIG. 12(b) is thinner than that of Ti, Cu and Ti layers in FIG. 12(a).

The structure of Ti, Cu and Ti layers in FIG. 12(a) is a conventional wiring structure, in which a diffusion layer is formed at the interface between the Ti and Cu layers. Because the diffusion layer at the interface is etched slower, the structure is difficultly controlled to have a cross-section of smooth trapezoid, and thus forms a poor cross-section structure of Cu over etching as shown in FIG. 8. For an alloy layer is formed at the interface between the adhesion layer and the Cu layer, the etching rate at the interface becomes slower.

On the other hand, the wiring structure of TiN, Cu and TiN layers in the invention has almost no alloy layer generated at the interface as in FIG. 2(b), and thus etching process can be controlled more easily. Therefore, the cross-section structure can be controlled to be better trapezoid-shaped more easily.

As illustrated in Table 3, by controlling N₂ amount relative to the total amount of N₂ and Ar in reaction sputtering process of adhesion layer, etching quality can be identified according to residue generated in etching. If there is residue, it represents that etching is not complete, which is denoted by x, and if there is no residue, it means etching is complete, which is denoted by ∘. Moreover, perform a peel test by using adhesive tape to identify the adhesion feature. If the film can be peeled by adhesive tape, it represents the film adhesion is poor, which is denoted by x. If the film cannot be peeled by adhesive tape, it means the film adhesion is good, which is denoted by ∘. In Table 3, it can be found that better etching quality and adhesion can be provided by using a suitable ratio of N₂ amount over total amount of N₂ and Ar.

TABLE 3

| | | | | | | |
|---|---|---|---|---|---|---|
| N₂ amount (sccm/total | 0.0 | 1.9 | 3.8 | 5.0 | 7.5 | 30 |
| amount: 150 sccm) | | | | | | |
| Residue | X | X | ◯ | ◯ | ◯ | ◯ |
| Adhesion (adhesive | ◯ | ◯ | ◯ | ◯ | ◯ | X |
| tape peel test) | | | | | | |

Moreover, the thickness of each layer in the wiring substrate which can restrain copper diffusion in the invention is not limited to that described in the embodiments mentioned above. The adhesion layer can be omitted to form a structure of copper wiring layer and diffusing barrier layer if the copper wiring layer can be adhered to the substrate or deposition layer.

Besides, the wiring substrate including a copper wiring layer can be particularly applied to a liquid crystal TV, or a personal computer monitor, or other displays.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

1. A wiring substrate, comprising:
a substrate;
a copper wiring layer, formed on the substrate, wherein the copper wiring layer is made of copper or a material containing copper as a principal component; and
a diffusing barrier layer, formed on an upper surface and sides of the copper wiring layer, wherein the diffusing barrier layer is made of metal containing nitrogen.

2. The wiring substrate according to claim 1, wherein an adhesion layer is formed under the copper wiring layer and comprises metal or metal containing nitrogen.

3. The wiring substrate according to claim 1, wherein the diffusing barrier layer comprises molybdenum nitride (MoN) and titanium nitride (TiN).

4. The wiring substrate according to claim 2, wherein the adhesion layer comprises Mo, MoN, Ti, and TiN.

5. The wiring substrate according to claim 1, wherein the copper wiring layer is directly formed upon the substrate.

6. The wiring substrate according to claim 1, wherein a deposition layer is formed on the substrate and the copper wiring layer is directly formed upon the deposition layer.

7. The wiring substrate according to claim 6, wherein the deposition layer comprises an insulation layer, a semiconductor layer, and a metal layer.

8. The wiring substrate according to claim 2, wherein the adhesion layer is directly formed upon the substrate.

9. The wiring substrate according to claim 2, wherein a deposition layer is formed on the substrate and the adhesion layer is directly formed upon the deposition layer.

10. The wiring substrate according to claim 9, wherein the deposition layer comprises an insulation layer, a semiconductor layer, and a metal layer.

11. A wiring substrate, comprising:
a substrate;
a copper wiring layer, formed above the substrate, wherein the copper wiring layer is made of copper or a material containing copper as a principal component; and
a diffusing barrier layer, formed on an upper surface of the copper wiring layer, wherein the diffusing barrier layer is made of metal containing nitrogen.

12. The wiring substrate according to claim 11, wherein an adhesion layer is formed under the copper wiring layer and comprises metal or metal containing nitrogen.

13. The wiring substrate according to claim 11, wherein the diffusing barrier layer comprises MoN and TiN.

14. The wiring substrate according to claim 12, wherein the adhesion layer comprises Mo, MoN, Ti, and TiN.

15. The wiring substrate according to claim 11, wherein the copper wiring layer is directly formed upon the substrate.

16. The wiring substrate according to claim 11, wherein a deposition layer is formed on the substrate and the wiring copper layer is directly formed upon the deposition layer.

17. The wiring substrate according to claim 16, wherein the deposition layer comprises an insulation layer, a semiconductor layer, and a metal layer.

18. The wiring substrate according to claim 12, wherein the adhesion layer is directly formed upon the substrate.

19. The wiring substrate according to claim 12, wherein a deposition layer is formed on the substrate and the adhesion layer is directly formed upon the deposition layer.

20. The wiring substrate according to claim 19, wherein the deposition layer comprises an insulation layer, a semiconductor layer, and a metal layer.

21. A method for forming a wiring substrate, comprising steps of:
preparing a substrate;
depositing a copper wiring layer on the substrate, wherein the copper wiring layer is made of copper or a material containing copper as a principal component;
patterning the copper wiring layer to form a copper wiring layer pattern;
depositing a diffusing barrier layer on the copper wiring layer pattern, wherein the diffusing barrier layer is made of metal containing nitrogen; and
patterning the diffusing barrier layer to distribute on an upper surface and sides of the copper wiring layer pattern.

22. The method according to claim 21, wherein the step of patterning the copper wiring layer comprises:
coating a photoresist on the copper wiring layer;
forming a photoresist pattern comprising photoresist covering region and a photoresist exposing region on the copper wiring layer by exposing from one side of the photoresist; and developing the photoresist□
etching the copper wiring layer located in the photoresist exposing region to form a copper wiring layer pattern.

23. The method according to claim 21, wherein the step of patterning the diffusing barrier layer comprises:
coating a photoresist on the diffusing barrier layer;
using the copper wiring layer as a mask to expose the substrate from the bottom side of the substrate;
developing the photoresist to form a photoresist covering region and a photoresist exposing region on the diffusing barrier layer; and
etching the diffusing barrier layer in the photoresist exposing region.

24. The method according to claim 21, wherein the step of depositing the diffusing barrier layer comprises performing a reaction sputtering process in which a nitrogen gas amount is 5% to 30% of the total amount of nitrogen gas and argon gas.

25. The method according to claim 22, wherein the etching step uses an etching solution comprising a mixture solution of phosphoric, acetic, and nitric acid or ammonia persulphate ((NH₄)₂S₂O₈) and hydrofluoric acid (HF).

26. The method according to claim 21, wherein the diffusing barrier layer comprises MoN and TiN.

27. A method for forming a wiring substrate, comprising steps of:
preparing a substrate;
depositing an adhesion layer on the substrate, wherein the adhesion layer is made of metal or metal containing nitrogen;
depositing a copper wiring layer on the adhesion layer, wherein the copper wiring layer is made of copper or a material containing copper as a principal component;
patterning the copper wiring layer to form a copper wiring layer pattern;
depositing a diffusing barrier layer on the copper wiring layer pattern, wherein the diffusing barrier layer is made of metal containing nitrogen; and
patterning the diffusing barrier layer to distribute on an upper surface and sides of the copper wiring layer pattern.

28. The method according to claim 27, wherein the step of patterning the copper wiring layer comprises:
coating a photoresist on the copper wiring layer;
forming a photoresist pattern comprising photoresist covering region and a photoresist exposing region on the copper wiring layer by exposing from one side of the photoresist; and developing the photoresist□
etching the copper wiring layer located in the photoresist exposing region to form a copper wiring layer pattern.

29. The method according to claim 27, wherein the step of patterning the diffusing barrier layer comprises:
coating a photoresist on the diffusing barrier layer;
using the copper wiring layer as a mask to expose the substrate from the bottom side of the substrate;
developing the photoresist to form a photoresist covering region and a photoresist exposing region on the diffusing barrier layer; and
etching the diffusing barrier layer in the photoresist exposing region.

30. The method according to claim 27, wherein in the step of etching the adhesion layer, the adhesion layer is etched along with the copper wiring layer in the step of patterning the copper wiring layer or is etched along with the diffusing barrier layer in the step of patterning the diffusing barrier layer, or is etched after the step of patterning the diffusing barrier layer.

31. The method according to claim 27, wherein the step of depositing the adhesion layer and the diffusing barrier layer comprises performing a reaction sputtering process in which a nitrogen gas amount is 5% to 30% of the total amount of nitrogen gas and argon gas.

32. The method according to claim 28, wherein the etching step uses an etching solution comprising a mixture solution of phosphoric, acetic, and nitric acid or ammonia persulphate ((NH₄)₂S₂O₈) and hydrofluoric acid (HF).

33. The method according to claim 27, wherein the diffusing barrier layer comprises MoN and TiN.

34. The method according to claim 27, wherein the adhesion layer comprises Mo, MoN, Ti, and TiN.

35. A method for forming a wiring substrate, comprising steps of:
preparing a substrate;
depositing a copper wiring layer on the substrate, wherein the copper wiring layer is made of copper or a material containing copper as a principal component;
depositing a diffusing barrier layer on the copper wiring layer pattern, wherein the diffusing barrier layer is made of metal containing nitrogen; and
patterning the diffusing barrier layer to distribute on an upper surface of the copper wiring layer pattern.

36. The method according to claim 35, wherein the step of patterning the diffusing barrier layer comprises:
coating a photoresist on the diffusing barrier layer;
exposing the photoresist;
developing the photoresist to form a photoresist covering region and a photoresist exposing region on the diffusing barrier layer; and
etching the diffusing barrier layer in the photoresist exposing region.

37. The method according to claim 35, wherein the step of depositing the diffusing barrier layer comprises performing a reaction sputtering process in which a nitrogen gas amount is 5% to 30% of the total amount of nitrogen gas and argon gas.

38. The method according to claim 36, wherein the etching step uses an etching solution comprising a mixture solution of phosphoric, acetic, and nitric acid or ammonia persulphate ((NH₄)₂S₂O₈) and hydrofluoric acid (HF).

39. The method according to claim 35, wherein the diffusing barrier layer comprises MoN and TiN.

40. A method for forming a wiring substrate, comprising steps of:
preparing a substrate;
depositing an adhesion layer on the substrate, wherein the adhesion layer is made of metal or metal containing nitrogen;
depositing a copper wiring layer on the adhesion layer, wherein the copper wiring layer is made of copper or a material containing copper as a principal component;
depositing a diffusing barrier layer on the copper wiring layer pattern, wherein the diffusing barrier layer is made of metal containing nitrogen; and
patterning the diffusing barrier layer to distribute on an upper surface of the copper wiring layer pattern.

41. The method according to claim 40, wherein the step of patterning the diffusing barrier layer comprises:
coating a photoresist on the diffusing barrier layer;
exposing the photoresist;
developing the photoresist to form a photoresist covering region and a photoresist exposing region on the diffusing barrier layer; and
etching the adhesion layer, the copper wiring layer, and the diffusing barrier layer in the photoresist exposing region.

42. The method according to claim 40, wherein the step of depositing the adhesion layer and the diffusing barrier layer comprises performing a reaction sputtering process in which a nitrogen gas amount is 5% to 30% of the total amount of nitrogen gas and argon gas.

43. The method according to claim 41, wherein the etching step uses an etching solution comprising a mixture solution of phosphoric, acetic, and nitric acid or ammonia persulphate ((NH₄)₂S₂O₈) and hydrofluoric acid (HF).

44. The method according to claim 40, wherein the diffusing barrier layer comprises MoN and TiN.

45. The method according to claim 40, wherein the adhesion layer comprises Mo, MoN, Ti, and TiN.

46. The method according to claim 23, wherein the etching step uses an etching solution comprising a mixture solution of phosphoric, acetic, and nitric acid or ammonia persulphate ((NH₄)₂S₂O₈) and hydrofluoric acid (HF).

47. The method according to claim 29, wherein the etching step uses an etching solution comprising a mixture solution of phosphoric, acetic, and nitric acid or ammonia persulphate ((NH₄)₂S₂O₈) and hydrofluoric acid (HF).

48. The method according to claim 30, wherein the etching step uses an etching solution comprising a mixture solution of phosphoric, acetic, and nitric acid or ammonia persulphate ((NH₄)₂S₂O₈) and hydrofluoric acid (HF).
